(19) United States
(12) Patent Application Publication
(10) Pub. No.: US 2026/0271494 A1
(43) Pub. Date: Sep. 10, 2026

(54) LIGHT-EMITTING ELEMENT, DISPLAY DEVICE, AND METHOD FOR FORMING LIGHT-EMITTING LAYER

(71) Applicant: Sharp Display Technology Corporation, Kameyama City, Mie (JP)

(72) Inventors: Yuma YAGUCHI, Sakai City, Osaka (JP); YOSHIHIRO UETA, Sakai City, Osaka (JP)

(21) Appl. No.: 19/120,854

(22) PCT Filed: Oct. 18, 2022
(86) PCT No.: PCT/JP2022/038713

§ 371 Date: Apr. 14, 2025

(51) Int. Cl. H10K 50/115; H10K 50/15; H10K 50/16

(52) U.S. Cl. CPC H10K 50/115; H10K 50/15; H10K 50/16

(57) ABSTRACT

A light-emitting element includes an anode, a cathode, and a light-emitting layer provided between the anode and the cathode, and the light-emitting layer includes a plurality of quantum dots a continuous compound provided around each of the plurality of quantum dots, and an electron transport material having electron transport properties.

### TECHNICAL FIELD

The disclosure relates to a light-emitting element, a display device, and a method for forming a light-emitting layer.

### BACKGROUND ART

In recent years, quantum dot light emitting diodes (QLEDs), which are light-emitting elements each including quantum dots, and display devices provided with QLEDs are attracting a lot of attention from a viewpoint that low power consumption, thinning, higher picture quality, and the like can be achieved. For this reason, a method for forming a light-emitting layer including quantum dots included in the QLED is also actively researched.

For example, as described in PTL 1, a voltage of the QLED is reduced by including quantum dot light-emitting layer in which a first surface in contact with a hole transport layer and a second surface in contact with the electron transport layer have organic ligand distributions different from each other.

### CITATION LIST

### Patent Literature

PTL 1: JP 2010-114079 A

### SUMMARY

### Technical Problem

Each of the ligands in the quantum dot light-emitting layer of the QLED described in PTL 1 is the organic ligand. The bond between the organic ligand and the quantum dot is a coordination bond, which is a very weak bond, and thus is easily released (desorbed) by contact with a solvent or other peripheral materials, heating, energization, or the like. Thus, a defect protection effect, which is a role of the ligand, is reduced, and the light-emission characteristics (external quantum efficiency (EQE)) and reliability of the QLED are reduced. In addition, when the surface of the quantum dot is not physically shielded by the ligand, oxygen, moisture, or the like easily comes into contact with the quantum dot itself, which may cause deterioration of the quantum dot itself or the like. In addition, the organic ligand does not have carrier transport properties, and thus it does not contribute to improvement of the carrier balance of the QLED.

An aspect of the disclosure has been made in view of the above-described problems, and an object of the disclosure is to provide a light-emitting element, a display device, and a method for forming a light-emitting layer which improves a carrier balance, an external quantum efficiency (EQE) and reliability.

### Solution to Problem

In order to solve the problems, a light-emitting element of the disclosure includes
an anode,
a cathode, and
a light-emitting layer provided between the anode and the cathode, in which
the light-emitting layer includes a plurality of quantum dots, a continuous compound provided around each of the plurality of quantum dots, and a carrier transport material having carrier transport properties.

In order to solve the problems, a display device of the disclosure includes
a first light-emitting element that emits light of a first color,
a second light-emitting element that emits light of a second color having a light-emission peak wavelength shorter than that of the light of the first color, and
a third light-emitting element that emits light of a third color having a light-emission peak wavelength shorter than that of the light of the second color, in which
the third light-emitting element is the light-emitting element.

In order to solve the problems, a method for forming a light-emitting layer of the disclosure forms at least part of a light-emitting layer by using a first solution including a plurality of quantum dots, a precursor of a continuous compound forming the continuous compound around each of the plurality of quantum dots, a carrier transport material having carrier transport properties, and a solvent.

### Advantageous Effects of Disclosure

According to an aspect of the disclosure, it is possible to provide a light-emitting element, a display device, and a method for forming a light-emitting layer which improves a carrier balance, an external quantum efficiency (EQE), and reliability.

### BRIEF DESCRIPTION OF DRAWINGS

FIG. 1 is a diagram for describing a tendency of a change rate of light emission intensity and a tendency of a luminance recovery in an energization stop period in a constant current driving test of a light-emitting element of a first embodiment and a light-emitting element of comparative example 1.

FIG. 2 is a schematic cross-sectional view illustrating a schematic configuration of the light-emitting element of comparative example 1.

FIG. 3 is a view for describing the reason why the change rate of the light emission intensity is large in the constant current driving test and the reason why the luminance recovery in the energization stop period is slow in the light-emitting element of comparative example 1.

FIG. 4 is a view for describing the reason why the change rate of the light emission intensity is large in the constant current driving test and the reason why the luminance recovery in the energization stop period is slow in the light-emitting element of comparative example 2.

FIG. 5 is a view for describing the reason why the change rate of the light emission intensity is large in the constant current driving test and the reason why the luminance recovery in the energization stop period is slow in the light-emitting element of comparative example 3.

FIG. 6 is a view for describing the reason why the change rate of the light emission intensity is large in the constant current driving test and the reason why the luminance recovery in the energization stop period is slow in the light-emitting element of comparative example 4.

FIG. 7 is a schematic cross-sectional view illustrating a schematic configuration of the light-emitting element of the first embodiment.

FIG. 8 is a view for describing a region formed between quantum dots when two quantum dots adjacent to each other among a plurality of quantum dots included in the light-emitting layer provided in the light-emitting element of the first embodiment illustrated in FIG. 7 are disposed close to each other.

FIG. 9 is a view for describing a region formed between quantum dots when two quantum dots adjacent to each other among the plurality of quantum dots included in the light-emitting layer provided in the light-emitting element of the first embodiment illustrated in FIG. 7 are slightly apart from each other.

FIG. 10 is views each for describing the reason why electrons are less likely to accumulate in the light-emitting layer or at an interface between the light-emitting layer and an electron transport layer in the light-emitting element of the first embodiment as compared with the light-emitting element of comparative example 1.

FIG. 11 is views each for describing the reason why the luminance recovery in the energization stop period is fast in the light-emitting element of the first embodiment as compared with the light-emitting element of comparative example 1.

FIG. 12 is a schematic cross-sectional view illustrating a schematic configuration of the light-emitting element of a second embodiment.

FIG. 13 is views each for describing the reason why electrons are less likely to accumulate in the light-emitting layer or at the interface between the light-emitting layer and the electron transport layer in the light-emitting element of the second embodiment as compared with the light-emitting element of comparative example 1.

FIG. 14 is a schematic cross-sectional view illustrating a schematic configuration of the light-emitting element of a third embodiment.

FIG. 15 is views each for describing the reason why electrons are less likely to accumulate in the light-emitting layer or at the interface between the light-emitting layer and the electron transport layer in the light-emitting element of the third embodiment as compared with the light-emitting element of comparative example 1.

FIG. 16 is a schematic cross-sectional view illustrating a schematic configuration of the light-emitting element of a fourth embodiment.

FIG. 17 is views each for describing the reason why holes are less likely to accumulate in the light-emitting layer or at an interface between the light-emitting layer and a hole transport layer in the light-emitting element of the fourth embodiment as compared with the light-emitting element of comparative example 2.

FIG. 18 is views each for describing the reason why the luminance recovery in the energization stop period is fast in the light-emitting element of the fourth embodiment as compared with the light-emitting element of comparative example 2.

FIG. 19 is a schematic cross-sectional view illustrating a schematic configuration of the light-emitting element of a fifth embodiment.

FIG. 20 is views each for describing the reason why holes are less likely to accumulate in the light-emitting layer or at an interface between the light-emitting layer and a hole transport layer in the light-emitting element of the fifth embodiment as compared with the light-emitting element of comparative example 2.

FIG. 21 is a schematic cross-sectional view illustrating a schematic configuration of the light-emitting element of a sixth embodiment.

FIG. 22 is views each for describing the reason why holes are less likely to accumulate in the light-emitting layer or at an interface between the light-emitting layer and a hole transport layer in the light-emitting element of the sixth embodiment as compared with the light-emitting element of comparative example 2.

FIG. 23 is a schematic cross-sectional view illustrating a schematic configuration of the light-emitting element of a seventh embodiment.

FIG. 24 is a schematic cross-sectional view illustrating a schematic configuration of the light-emitting element of an eighth embodiment.

FIG. 25 is a schematic cross-sectional view illustrating a schematic configuration of a display device of a ninth embodiment.

### DESCRIPTION OF EMBODIMENTS

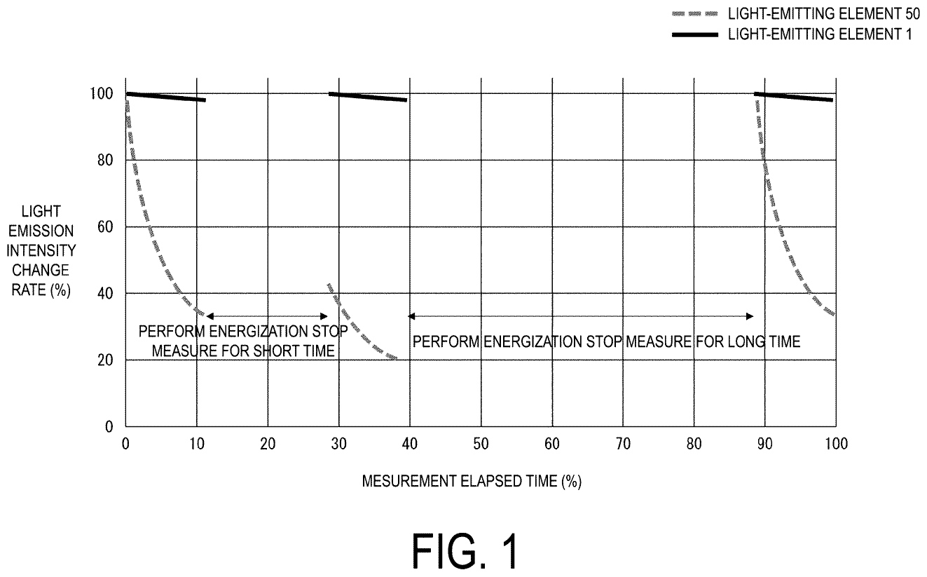

Embodiments of the disclosure will be described with reference to FIGS. 1 to 25 as follows. Hereinafter, for convenience of description, configurations having the same functions as those described in a specific embodiment are denoted by the same reference signs, and descriptions thereof will be omitted.

### First Embodiment

FIG. 1 is a diagram for describing a tendency of a change rate of light emission intensity and a tendency of a luminance recovery in an energization stop period in a constant current driving test of a light-emitting element 1 of a first embodiment and a light-emitting element 50 of comparative example 1.

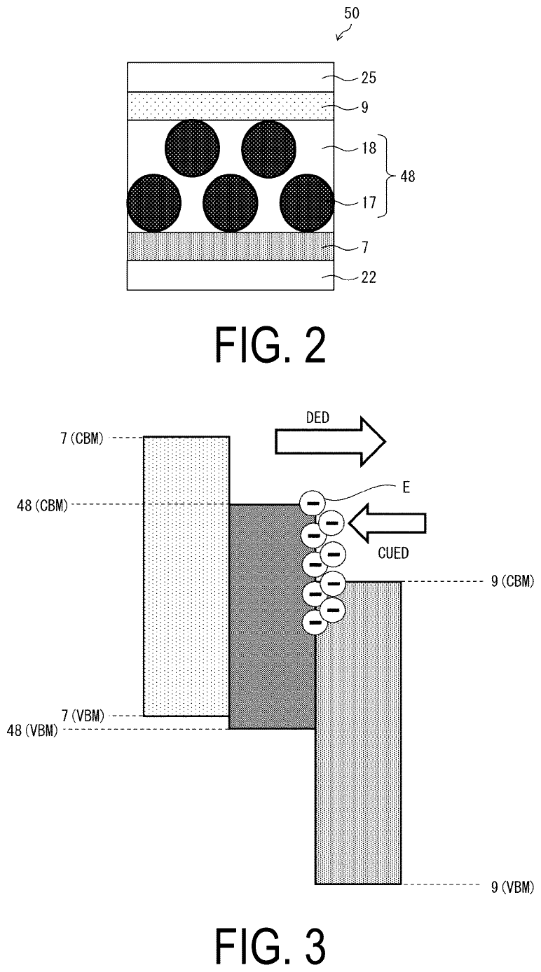

FIG. 2 is a schematic cross-sectional view illustrating a schematic configuration of the light-emitting element 50 of comparative example 1.

FIG. 3 is a view for describing the reason why the change rate of the light emission intensity is large in the constant current driving test and the reason why the luminance recovery in the energization stop period is slow in the light-emitting element 50 of comparative example 1.

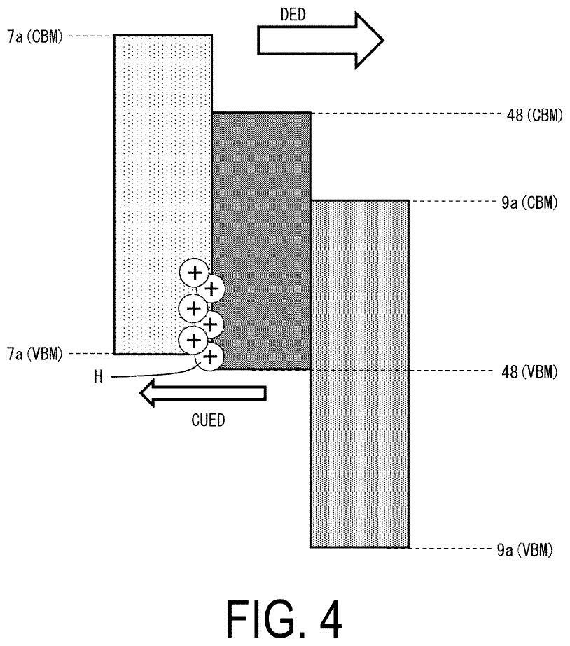

FIG. 4 is a view for describing the reason why the change rate of the light emission intensity is large in the constant current driving test and the reason why the luminance recovery in the energization stop period is slow in the light-emitting element 50a of comparative example 2.

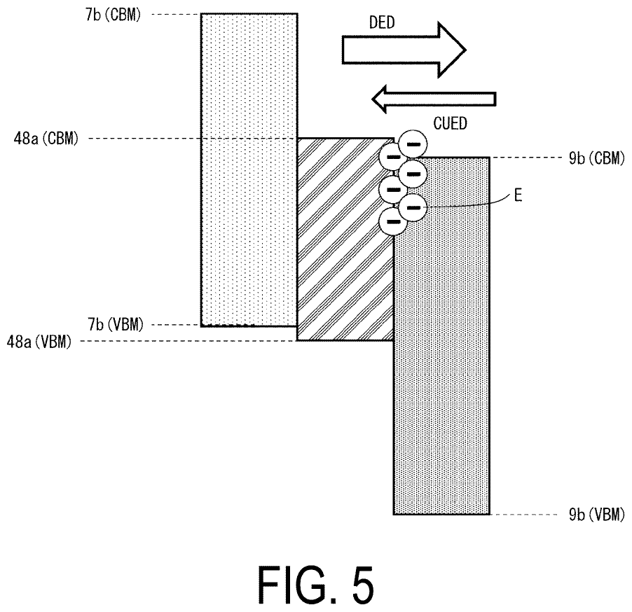

FIG. 5 is a view for describing the reason why the change rate of the light emission intensity is large in the constant current driving test and the reason why the luminance recovery in the energization stop period is slow in the light-emitting element of comparative example 3.

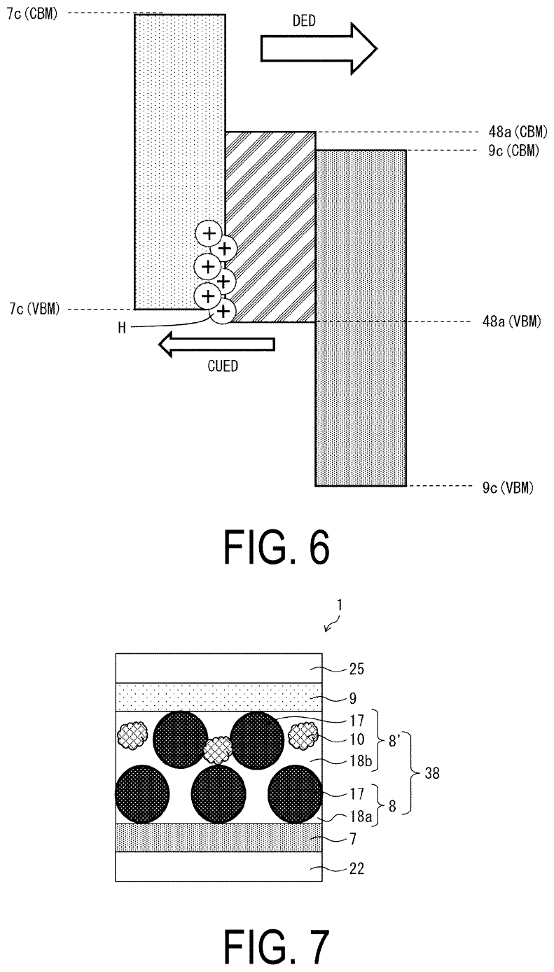

FIG. 6 is a view for describing the reason why the change rate of the light emission intensity is large in the constant current driving test and the reason why the luminance recovery in the energization stop period is slow in the light-emitting element of comparative example 4.

In general, a QLED is likely to be in a poor carrier balance state in which either holes or electrons as carriers are excessive.

The light-emitting element 50 of comparative example 1 illustrated in FIGS. 2 and 3 and the light-emitting element of comparative example 3 illustrated in FIG. 5 are examples of light-emitting elements in an electron-excess state.

As illustrated in FIG. 2, the light-emitting element 50 includes an anode 22, a cathode 25, and a light-emitting layer 48 provided between the anode 22 and the cathode 25. Further, a hole transport layer 7 is included between the anode 22 and the light-emitting layer 48, and an electron transport layer 9 is included between the cathode 25 and the light-emitting layer 48.

The light-emitting layer 48 includes a plurality of quantum dots 17 and a continuous compound 18, for example, a matrix provided around each of the plurality of quantum dots 17. In a case where the light-emitting layer 48 includes an organic ligand, the continuous compound 18, for example, the matrix can suppress a decrease in an external quantum efficiency (EQE) and a decrease in reliability caused by the organic ligand.

On the other hand, in a case where the light-emitting layer 48 includes the continuous compound 18, for example, a matrix, having no electron transport properties as illustrated in FIG. 3, the conduction band minimum (CBM) of the light-emitting layer 48 is shallow and the conduction band minimum (CBM) of the electron transport layer 9 is deeper than the conduction band minimum (CBM) of the light-emitting layer 48, and thus the difference between the conduction band minimum (CBM) of the light-emitting layer 48 and the conduction band minimum (CBM) of the electron transport layer 9 is large, and electrons E, which are excessively present carriers, tend to accumulate in the light-emitting layer 48 or at an interface between the light-emitting layer 48 and the electron transport layer 9. The quantum dot 17 included in the light-emitting layer 48 illustrated in FIG. 3 is a quantum dot corresponding to a wavelength region of blue light in which the difference between the conduction band minimum (CBM) and the valence band maximum (VBM) is relatively large, and the continuous compound 18, for example, the matrix included in the light-emitting layer 48 illustrated in FIG. 3 is formed of a material having highly insulating properties in which the difference between the conduction band minimum (CBM) and the valence band maximum (VBM) is relatively large.

Similarly, as illustrated in FIG. 5, in a case where a light-emitting layer 48a includes the continuous compound 18, for example, the matrix having no electron transport properties, the conduction band minimum (CBM) of the light-emitting layer 48a is shallow and the conduction band minimum (CBM) of an electron transport layer 9b is deeper than the conduction band minimum (CBM) of the light-emitting layer 48a, and thus the difference between the conduction band minimum (CBM) of the light-emitting layer 48a and the conduction band minimum (CBM) of the electron transport layer 9b is large, and the electrons E, which are excessively present carriers, tend to accumulate in the light-emitting layer 48a or at the interface between the light-emitting layer 48a and the electron transport layer 9b. The quantum dot included in the light-emitting layer 48a illustrated in FIG. 5 is a quantum dot in which the difference between the conduction band minimum (CBM) and the valence band maximum (VBM) corresponds to a wavelength region of red light or green light, and the continuous compound 18, for example, the matrix included in the light-emitting layer 48a illustrated in FIG. 5 is formed of a material having highly insulating properties in which the difference between the conduction band minimum (CBM) and the valence band maximum (VBM) is relatively large.

As described above, in each of the light-emitting element 50 of comparative example 1 illustrated in FIG. 3 and the light-emitting element of comparative example 3 illustrated in FIG. 5, the electrons E, which are excessively present carriers, tend to accumulate in the light-emitting layers 48 and 48a or at the interfaces between the light-emitting layers 48 and 48a and the electron transport layers 9 and 9b.

In a constant current driving period of the light-emitting element 50 of comparative example 1 illustrated in FIG. 2 and the light-emitting element of comparative example 3 illustrated in FIG. 5, the electrons E, which are excessively present carriers, accumulate in the light-emitting layers 48 and 48a or at interfaces between the light-emitting layers 48 and 48a and the electron transport layers 9 and 9b, thus generating an electrical field CUED in a direction opposite to an electrical field DED at the time of driving the light-emitting element 50 of comparative example 1 and the light-emitting element of comparative example 3 and generating a decrease in luminance of the light-emitting element 50 of comparative example 1 and the luminance of the light-emitting element of comparative example 3. FIG. 1 shows, as an example, a generated decrease in luminance of the light-emitting element 50, that is, the change rate of the light emission intensity during the constant current driving period of the light-emitting element 50 of comparative example 1. There is a problem in that such a decrease in luminance of the light-emitting element causes a decrease in an external quantum efficiency (EQE) of the light-emitting element, that is, a decrease in a luminous efficiency. In addition, in the case of the light-emitting element 50 of comparative example 1 and the light-emitting element of comparative example 3, there is also a problem in that the carrier balance cannot be improved.

The light-emitting element of comparative example 2 illustrated in FIG. 4 and the light-emitting element of comparative example 4 illustrated in FIG. 6 are examples of light-emitting elements in a hole-excess state.

As illustrated in FIGS. 4 and 6, the light-emitting layers 48 and 48a respectively include the plurality of quantum dots and the continuous compound 18, for example, the matrix provided around each of the plurality of quantum dots. In the case where the light-emitting layers 48 and 48a respectively include the organic ligand, the continuous compound 18, for example, the matrix can suppress a decrease in an external quantum efficiency (EQE) and a decrease in reliability caused by the organic ligand.

On the other hand, in a case where the light-emitting layers 48 and 48a respectively include the continuous compound 18, for example, a matrix having no hole transport properties, as illustrated in FIGS. 4 and 6, the valence band maximum (VBM) of the light-emitting layers 48 and 48a is deep and the valence band maximum (VBM) of hole transport layers 7a and 7c is deeper than the valence band maximum (VBM) of the light-emitting layers 48 and 48a, and thus the difference between the valence band maximum (VBM)) of the light-emitting layers 48 and 48a and the valence band maximum (VBM) of the hole transport layers 7a and 7c is large, and holes H, which are excessively present carriers, tend to accumulate in the light-emitting layers 48 and 48a or at the interfaces between the light-emitting layers 48 and 48a and the hole transport layers 7a and 7c.

As described above, in each of the light-emitting element of comparative example 2 illustrated in FIG. 4 and the light-emitting element of comparative example 4 illustrated in FIG. 6, the holes H, which are excessively present carriers, tend to accumulate in the light-emitting layers 48 and 48a or at the interfaces between the light-emitting layers 48 and 48a and the hole transport layers 7a and 7c.

In the constant current driving period of the light-emitting element of comparative example 2 illustrated in FIG. 4 and the light-emitting element of comparative example 4 illustrated in FIG. 6, the holes H, which are excessively present carriers, accumulate in the light-emitting layers 48 and 48a or at interfaces between the light-emitting layers 48 and 48a and the hole transport layers 7a and 7c, thus generating the electrical field CUED in a direction opposite to the electrical field DED at the time of driving the light-emitting element of comparative example 2 and the light-emitting element of comparative example 4 and generating a decrease in luminance of the light-emitting element of comparative example 2 and luminance of the light-emitting element of comparative example 4. There is a problem in that such a decrease in luminance of the light-emitting element causes a decrease in the external quantum efficiency (EQE) of the light-emitting element, that is, a decrease in the luminous efficiency. In addition, in the case of the light-emitting element of comparative example 2 and the light-emitting element of comparative example 4, there is also a problem in that the carrier balance cannot be improved.

Thus, the light-emitting element 1 of the first embodiment in which a light-emitting layer 38 includes an electron transport material 10 having electron transport properties as the carrier transport material having carrier transport properties will be described with reference to FIGS. 7 to 11.

FIG. 7 is a schematic cross-sectional view illustrating a schematic configuration of the light-emitting element 1 of the first embodiment.

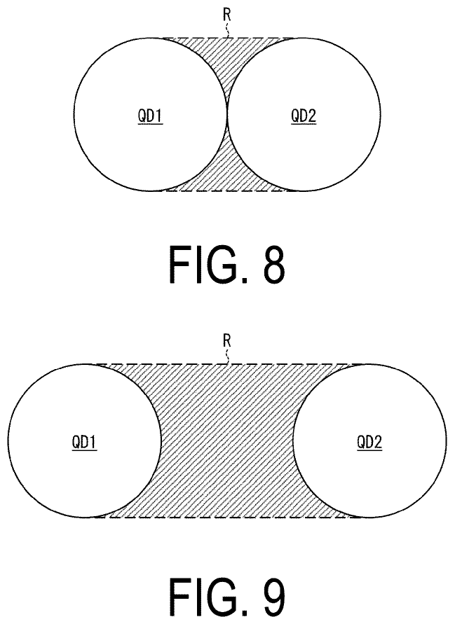

FIG. 8 is a view for describing a region R formed between the quantum dots QD1 and QD2 when two quantum dots QD1 and QD2 adjacent to each other among the plurality of quantum dots 17 included in the light-emitting layer 38 provided in the light-emitting element 1 of the first embodiment illustrated in FIG. 7 are disposed close to each other.

FIG. 9 is a view for describing a region R formed between the quantum dots QD1 and QD2 when two quantum dots QD1 and QD2 adjacent to each other among the plurality of quantum dots 17 included in the light-emitting layer 38 provided in the light-emitting element 1 of the first embodiment illustrated in FIG. 7 are disposed slightly apart from each other.

As illustrated in FIG. 7, the light-emitting element 1 includes the anode 22, the cathode 25, and the light-emitting layer 38 provided between the anode 22 and the cathode 25. The light-emitting layer 38 includes the plurality of quantum dots 17, a continuous first compound 18a and a continuous second compound 18b provided around each of the plurality of quantum dots 17, and the electron transport material 10 having electron transport properties as the carrier transport material having carrier transport properties.

The “continuous compound provided around each of the plurality of quantum dots” includes not only a continuous compound formed by one step but also a case where the continuous first compound 18a and the continuous second compound 18b formed by two different steps are provided so as to be in contact with each other as in the present embodiment.

The “compounds are continuous” means a state in which the compounds of interest are continuously present without being partitioned from each other by other compounds. The compounds of interest may be one or two or more. The compounds of interest may be chemically bonded to each other, may be disposed within a range in which an intermolecular force acts to each other, or may be merely physically in contact with each other.

In the present embodiment, a case where a continuous compound composed of the continuous first compound 18a and the continuous second compound 18b provided so as to be in contact with each other is provided around each of the plurality of quantum dots 17 will be described as an example, but the present embodiment is not limited thereto. For example, one of the continuous first compound 18a and the continuous second compound 18b may be provided around each of the plurality of quantum dots 17.

In the present embodiment, as illustrated in FIG. 7, a case where the light-emitting element 1 includes the hole transport layer 7 as a hole function layer between the anode 22 and the light-emitting layer 38, and the electron transport layer 9 as an electron function layer between the cathode 25 and the light-emitting layer 38 will be described as an example, but the present embodiment is not limited thereto. The light-emitting element 1 may include at least one of a hole transport layer or a hole injection layer as the hole function layer, and may include at least one of an electron transport layer or an electron injection layer as the electron function layer. The light-emitting element 1 may not include at least one of the hole function layer or the electron function layer.

In the present embodiment, a case where the continuous compound composed of the continuous first compound 18a and the continuous second compound 18b provided so as to be in contact with each other is a matrix of an inorganic compound and the matrix of the inorganic compound includes the electron transport material 10 having electron transport properties, which is a carrier transport material having the carrier transport properties, will be described as an example, but the present embodiment is not limited thereto.

In the present embodiment, a case where each of the continuous first compound 18a and the continuous second compound 18b is the same inorganic compound will be described as an example, but the present embodiment is not limited thereto and the compounds may be different inorganic compounds. Furthermore, each of the continuous first compound 18a and the continuous second compound 18b may be a matrix including one or more selected from an inorganic compound, an organic polymer compound, and an organic and inorganic hybrid compound. For example, the continuous first compound 18a may be the matrix of the inorganic compound, and the continuous second compound 18b may be the matrix of the organic polymer compound or the matrix of the organic and inorganic hybrid compound.

The matrix means a member that includes and holds other objects, and can be referred to as a base material or a filler. The matrix may be solid at room temperature. The matrix may be a member that includes and holds the quantum dots 17. The matrix including one or more compounds selected from the inorganic compound, the organic polymer compound, and the organic and inorganic hybrid compound or the matrix of the inorganic compound may be a member that can include and hold the quantum dots 17. In the disclosure, a case where the quantum dots 17 are not evenly distributed in the matrix is also included. Further, a region of the matrix in which a region of a certain matrix does not include the quantum dots 17 is also allowed.

The matrix of the inorganic compound, which is an example of the matrix, may fill spaces between the plurality of quantum dots 17. The “matrix of the inorganic compound fills spaces between the plurality of quantum dots 17” means that the matrix of the inorganic compound fills spaces between at least two quantum dots 17. The “matrix of the inorganic compound fills spaces between the two quantum dots 17” means that the region R illustrated in FIGS. 8 and 9 is filled or suffused with the matrix of the inorganic compound. The region R is a region surrounded by two straight lines (common circumscribed line) in contact with the outer peripheries of the two quantum dots QD1 and QD2 adjacent to each other and the facing outer peripheries of the two quantum dots adjacent to each other QD1 and QD2. Even when the two quantum dots QD1 and QD2 adjacent to each other are disposed close to each other as illustrated in FIG. 8 or even when the two quantum dots QD1 and QD2 adjacent to each other are disposed slightly apart from each other as illustrated in FIG. 9, the region R is present and is filled with the matrix. In the disclosure, the two quantum dots QD1 and QD2 adjacent to each other may be held by the presence of the matrix of the inorganic compound in the region R. For example, at least part of the region R may be filled with the matrix.

In the present embodiment, a case where the region R formed between the two quantum dots QD1 and QD2 adjacent to each other illustrated in FIGS. 8 and 9, that is, the spaces between the plurality of quantum dots 17 are filled with the matrix of the inorganic compound will be described as an example, but the present embodiment is not limited thereto.

The “quantum dots QD1 and QD2 are held by the matrix present in the region R formed between the quantum dots QD1 and QD2” means that at least part of the region R is filled with the matrix, and includes not only a case where the matrix fills the entire region R but also a case where the matrix fills part of the region R.

The matrix of the inorganic compound, which is an example of the matrix, may be formed so as to fill a region (space) other than the plurality of quantum dots 17 of the light-emitting layer 38. Alternatively, the matrix of the inorganic compound may constitute an outer edge of the light-emitting layer 38 in matrix, and the plurality of quantum dots 17 may be located away from the outer edge. That is, the matrix of the inorganic compound may include the plurality of quantum dots 17. Furthermore, at least part of the outer edge of the light-emitting layer 38 may be constituted by the matrix and the quantum dots 17. Each of the plurality of quantum dots 17 may be embedded in the matrix of the inorganic compound at an interval. Here, the outer edge means an upper face and a lower face of the light-emitting layer 38.

The matrix of the inorganic compound, which is an example of the matrix, may include a continuous film having an area equal to or greater than 1000 nm² in a plane direction orthogonal to a layer thickness direction of the light-emitting layer 38. The continuous film means a film not partitioned by a material other than a material constituting the continuous film in one plane. The continuous film may be in the form of an integrated film connected without interruption by chemical bonding of the material constituting the matrix.

The matrix of the inorganic compound may be the same material as that of a shell of the quantum dot 17. In this case, an average distance (core-to-core distance) between cores of the quantum dots 17 adjacent to each other may be equal to or greater than 3 nm or may be equal to or greater than 5 nm. Alternatively, the average distance between cores of the quantum dots 17 adjacent to each other may be 0.5 times or more the average core diameter of the quantum dots 17. The average distance (core-to-core distance) between cores of the quantum dots 17 adjacent to each other is obtained by averaging distances of 20 cores adjacent to each other in a space including the 20 cores. The average distance (core-to-core distance) of the cores may be kept wider than the distance of the cores when the shells are in contact with each other. The average core diameter of the quantum dots 17 is obtained by averaging the core diameters of 20 cores of the quantum dots 17 in a cross-sectional observation in a space including the 20 quantum dots 17. The core diameter of the quantum dot 17 can be the diameter of a circle having the same area as the core area of the quantum dot 17 in the cross-sectional observation.

The constituent material of the matrix of the inorganic compound, that is, each of the continuous first compound 18a and the continuous second compound 18b provided around each of the plurality of quantum dots 17 may be, for example, a metal sulfide and/or a metal oxide. The metal sulfide may be, for example, a zinc sulfide (ZnS), a zinc magnesium sulfide (ZnMgS, ZnMgS₂), a gallium sulfide (GaS, Ga₂S₃), a zinc tellurium sulfide (ZnTeS), a magnesium sulfide (MgS), a zinc gallium sulfide (ZnGa₂S₄), and a magnesium sulfide (MgGa₂S₄). The metal oxide may be, for example, a zinc oxide (ZnO), a titanium oxide (TiO₂), a tin oxide (SnO₂), tungsten oxide (WO₃), and a zirconium oxide (ZrO₂). Note that a chemical formula written within parentheses after a compound name is a representative example. In addition, the composition ratio described in the chemical formula is desirably stoichiometry in which the actual composition of the compound is the same as the chemical formula but is not necessarily stoichiometry.

Unless otherwise specified or contradicted, a desired structure of the matrix or the like need not be observed over the entire area of the light-emitting layer 38 as long as the desired structure is obtained by observing the cross section of the light-emitting layer 38 in the range of about 100 nm. The matrix may include a substance different from the main material (for example, an inorganic substance such as an inorganic semiconductor), for example, as an additive.

The constituent material of the matrix, that is, each of the continuous first compound 18a and the continuous second compound 18b provided around each of the plurality of quantum dots 17 may be, for example, the organic polymer compound or the organic and inorganic hybrid compound. The organic polymer compound may be, for example, a polymethyl methacrylate resin (MMA), a biaxially oriented polystyrene sheet (OPS), polystyrene (PS), or polycarbonate (PC). The organic and inorganic hybrid compound may be, for example, polysilsesquioxane, which is a siloxane-based polymer, MAPbI₃, which is a perovskite-based crystal material, or the like.

As illustrated in FIG. 7, the light-emitting layer 38 provided in the light-emitting element 1 includes a first portion 8 and a second portion 8′. The first portion 8 is provided closer to the anode 22 than the second portion 8′, and a concentration of the electron transport material 10 having electron transport properties and included in the second portion 8′ is higher than a concentration of the electron transport material 10 having electron transport properties and included in the first portion 8.

In present embodiment, a case where the first portion 8 is composed of the plurality of quantum dots 17 and the continuous first compound 18a provided around each of the plurality of quantum dots 17, and the second portion 8′ is composed of the plurality of quantum dots 17, the continuous second compound 18b provided around each of the plurality of quantum dots 17, and the electron transport material 10 having electron transport properties will be described as an example, but the present embodiment is not limited thereto. The electron transport material 10 having electron transport properties may be included also in the first portion 8 as long as the concentration of the electron transport material 10 having electron transport properties and included in the second portion 8′ is higher than the concentration of the electron transport material 10 having electron transport properties and included in the first portion 8. Furthermore, the light-emitting layer 38 may have a concentration gradient of the electron transport material 10 in which the concentration of the electron transport material 10 gradually increases from the hole transport layer 7 toward the electron transport layer 9.

The electron transport material 10 having electron transport properties may be nanoparticles of a metal oxide including at least one selected from Zn, Mg, Ti, Si, Sn, W, Ta, Ba, Zr, Al, Y, and Hf, and may be, for example, nanoparticles of a zinc oxide or a magnesium zinc oxide.

The electron transport material 10 having electron transport properties may be an organic monomer having electron transport properties, and the organic monomer having electron transport properties may be, for example, TPBi, B4PyMPy, or BCP.

The electron transport material 10 having electron transport properties is preferably an organic semiconductor. In a case where the electron transport material 10 having electron transport properties is an inorganic semiconductor, there is a possibility that a change with a very small amount in the Fermi level due to contact between semiconductors causes a large change and a large barrier. On the other hand, in the case of the organic semiconductor, the change in the Fermi level due to contact between semiconductors is very gentle, and the dependence of the change in the Fermi level on contact amount is low. Thus, the electron level can be easily controlled, an injection barrier for the electrons E is less likely to be generated, and favorable injection characteristics for the electrons E can be ensured.

The total weight of the electron transport material 10 having electron transport properties and included in the light-emitting layer 38 is preferably 10% or less, and more preferably 1% or less of the total weight of the plurality of quantum dots 17 included in the light-emitting layer 38. The total weight of the electron transport material 10 having electron transport properties and included in the second portion 8′ is preferably about 70% or less of the total weight of the plurality of quantum dots 17 included in the second portion 8′. Within such a range, good injection characteristics of the electrons E into the quantum dots 17 can be ensured.

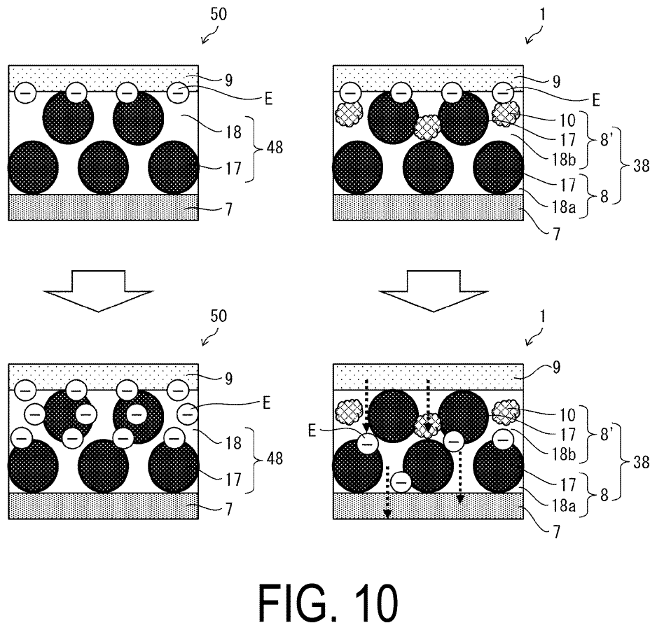

FIG. 10 is views each for describing the reason why the electrons E are less likely to accumulate in the light-emitting layer 38 or at an interface between the light-emitting layer 38 and the electron transport layer 9 in the light-emitting element 1 of the first embodiment as compared with the light-emitting element 50 of comparative example 1.

The light-emitting element 50 of comparative example 1 and the light-emitting element 1 of the first embodiment illustrated in FIG. 10 are examples of the light-emitting elements in the electron-excess state.

In the case of the light-emitting element 50 of comparative example 1 illustrated in FIG. 10, the electrons E, which are excessively present carriers, accumulate in the light-emitting layer 48 or at an interface between the light-emitting layer 48 and an electron transport layer 9 with a lapse of time of the constant current driving period, thus generating an electrical field in a direction opposite to the electrical field at the time of driving the light-emitting element 50, and generating a decrease in luminance of the light-emitting element 50 as illustrated in FIG. 1. There is a problem in that such a decrease in luminance causes a decrease in luminous efficiency of the light-emitting element 50. The electrical field in the opposite direction can be canceled by increasing the drive voltage of the light-emitting element 50. However, in such a case, there is a problem in that a large stress is applied to the materials of the layers constituting the light-emitting element 50 and the reliability is greatly reduced.

On the other hand, in the case of the light-emitting element 1 of the first embodiment illustrated in FIG. 10, since the electron transport material 10 having electron transport properties is dispersed in the light-emitting layer 38, the electrons E, which are excessively present carriers, are gradually diffused to the hole transport layer 7 via the electron transport material 10 having electron transport properties three-dimensionally present around the electrons E, and are quenched and consumed by recombining with the hole transport layer 7. In order to suppress the occurrence of light emission when the electrons E recombine with the hole transport layer 7, it is preferable to use a non-light-emitting material as the hole transport layer 7. As the non-light-emitting material, for example, a material having a band gap (Eg) of 3.5 eV or more can be used. According to the configuration of the light-emitting element 1, the electrons E, which are excessively present carriers even when the time of the constant current driving period has elapsed, are less likely to accumulate, and the decrease in luminance of the light-emitting element 1 can be suppressed as illustrated in FIG. 1. Thus, according to the light-emitting element 1, the carrier balance, the external quantum efficiency (EQE), and the reliability can be improved.

The electrons E, which are excessively present carriers even during the energization stop period, that is, the period during which the light-off state is maintained, are gradually diffused into the hole transport layer 7 via the electron transport material 10 having electron transport properties three-dimensionally present around the electrons E, and are quenched and consumed by recombining with the hole transport layer 7. Thus the luminance recovery in the energization stop period is fast in the light-emitting element 1 of the first embodiment as illustrated in FIG. 1.

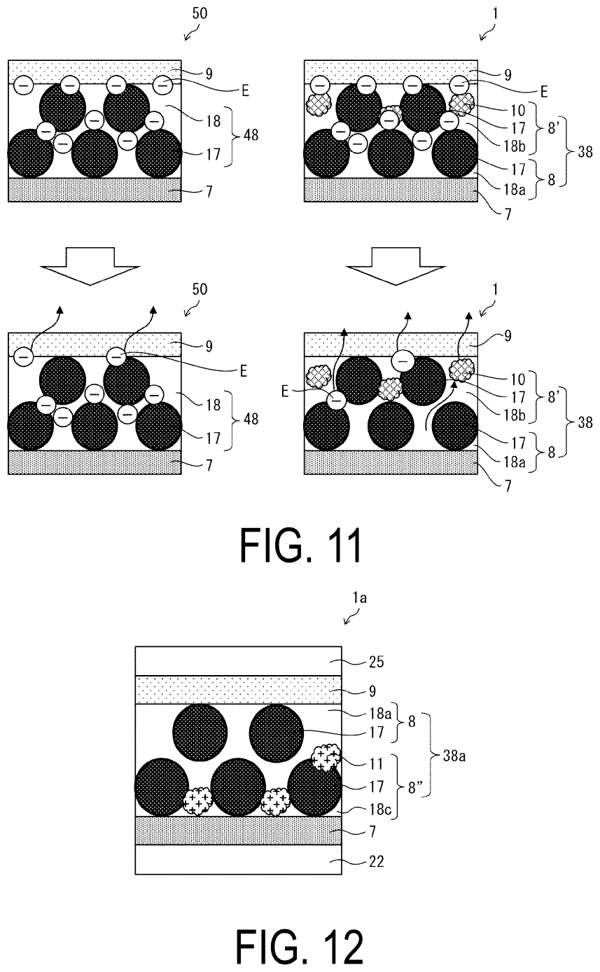

FIG. 11 is views each for describing the reason why the luminance recovery in the energization stop period is fast in the light-emitting element 1 of the first embodiment as compared with the light-emitting element 50 of comparative example 1.

In the light-emitting element 50 of comparative example 1 and the light-emitting element 1 of the first embodiment illustrated in FIG. 11, the electrons E accumulated in the light-emitting layers 38 and 48 or at the interface between the light-emitting layers 38 and 48 and the electron transport layer 9 are gradually diffused toward the cathode 25 side by maintaining the energization stop period, that is, the light-off state, and eventually return to a drive start initial state. However, in the case of the light-emitting element 50 of comparative example 1, as illustrated in FIG. 11, the electrons E accumulated at the interface between the light-emitting layer 48 and the electron transport layer 9 are diffused to the cathode 25 side at a relatively early stage of the energization stop period, but the electrons E accumulated in the light-emitting layer 48 remain without being diffused to the cathode 25 side even after a relatively long energization stop period has elapsed. Thus, as illustrated in FIG. 1, in the light-emitting element 50 of comparative example 1, the luminance does not recover when an energization stop measure is performed for a short time, and the luminance can recover when the energization stop measure is performed for a long time, so that the luminance recovery in the energization stop period is slow.

On the other hand, in the case of the light-emitting element 1 of the first embodiment illustrated in FIG. 10, since the electron transport material 10 having electron transport properties is dispersed in the light-emitting layer 38, the electrons E accumulated in the light-emitting layer 38 or at the interface between the light-emitting layer 38 and the electron transport layer 9 are rapidly diffused to the cathode 25 side via the electron transport material 10 having electron transport properties three-dimensionally present around the electrons E. Thus, as illustrated in FIG. 1, in the light-emitting element 1 of the first embodiment, the luminance recovery in the energization stop period is fast.

In the light-emitting element 1 of the present embodiment, in order to obtain both an effect illustrated in FIG. 10 in which the electrons E, which are excessively present carriers, are less likely to accumulate and an effect illustrated in FIG. 11 in which the electrons E, which are excessively present carriers, are rapidly diffused toward the cathode 25 side, the concentration of the electron transport material 10 included in the second portion 8′ is higher than the concentration of the electron transport material 10 included in the first portion 8. However, in order to obtain only the effect illustrated in FIG. 10 in which the electrons E, which are excessively present carriers, are less likely to accumulate, the electron transport material 10 having electron transport properties may be simply included in the light-emitting layer 38, or the electron transport material 10 having electron transport properties may be uniformly dispersed in the light-emitting layer 38. In the case of the configuration in which the electron transport material 10 having electron transport properties is simply included in the light-emitting layer 38 or the configuration in which the electron transport material 10 having electron transport properties is uniformly dispersed in the light-emitting layer 38, it is preferable that the electron transport material 10 having electron transport properties is not in contact with the hole transport layer 7.

The light-emitting layer 38 provided in the light-emitting element 1 of the present embodiment may include a plurality of ligands, and the plurality of ligands may be one or more selected from an organic ligand, an inorganic ligand, and a halogen ligand.

The quantum dot 17 included in the light-emitting layer 38 provided in the light-emitting element 1 of the present embodiment may have, for example, a core structure, a core/shell structure, a core/shell/shell structure, or a core/shell structure with continuously varying a ratio. Note that the shell may completely cover the core, or may partially cover the core. The core may be composed of, for example, Si, C, or the like in a case of a unitary system, composed of, for example, CdSe, CdS, CdTe, InP, GaP, InN, ZnSe, ZnS, ZnTe, or the like in a case of a binary system, composed of, for example, CdSeTe, GaInP, ZnSeTe, or the like in a case of a ternary system, and composed of, for example, AgInGaS (AIGS) or the like in a case of a quaternary system. The shell can be composed of, for example, CdS, CdTe, CdSe, ZnS, ZnSe, ZnTe, or the like in a case of a binary system, and composed of, for example, CdSSe, CdTeSe, CdSTe, ZnSSe, ZnSTe, ZnTeSe, AgInP (AIP), or the like in a case of a ternary system.

Note that the quantum dot 17 is a dot having a maximum width of 100 nm or less. The shape of the quantum dot 17 is not particularly limited as long as it is within a range satisfying the maximum width, and the shape is not limited to a spherical three-dimensional shape (circular cross-sectional shape). The shape of the quantum dot 17 may be, for example, a polygonal cross-sectional shape, a rod-shaped three-dimensional shape, a branch-shaped three-dimensional shape, or a three-dimensional shape having unevenness on the surface thereof, or a combination of them.

The quantum dot 17 typically may be composed of a semiconductor. The semiconductor may have a constant band gap. The semiconductor may be a material capable of emitting light and may include at least a material which will be described below. The semiconductor may emit each of red light, green light, and blue light. The semiconductor includes, for example, at least one kind selected from the group consisting of a group II-VI compound, a group III-V compound, and a chalcogenide and a perovskite compound. Note that the group II-VI compound refers to a compound including a group II element and a group VI element, and the group III-V compound refers to a compound including a group III element and a group V element. Further, the group II element may include a group 2 element and a group 12 element, the group III element may include a group 3 element and a group 13 element, the group V element may include a group 5 element and a group 15 element, and the group VI element may include a group 6 element and a group 16 element.

Examples of the group II-VI compound include, for example, at least one kind selected from the group consisting of MgS, MgSe, MgTe, CaS, CaSe, CaTe, SrS, SrSe, SrTe, BaS, BaSe, BaTe, ZnS, ZnSe, ZnTe, CdS, CdSe, CdTe, HgS, HgSe, and HgTe.

Examples of the group III-V compound include, for example, at least one kind selected from the group consisting of GaAs, GaP, InN, InAs, InP, and InSb.

The chalcogenide is a compound including a group VI A (16) element, and includes, for example, CdS or CdSe. The chalcogenide may include a mixed crystal thereof.

The perovskite compound has, for example, a composition represented by a general formula CsPbX₃. Examples of the constituent element X include at least one kind selected from the group consisting of Cl, Br, and I.

Here, the numbering of groups of an element by using Roman numerals is numbering based on the old International Union of Pure and Applied Chemistry (IUPAC) system or old Chemical Abstracts Service (CAS) system, and the numbering of groups of an element by using Arabic numerals is numbering based on the current IUPAC system.

In present embodiment, as illustrated in FIG. 7, the light-emitting element 1 includes the anode 22 and the cathode 25 provided as an upper layer than the anode 22, and a light-emitting element having a normally layered structure in which the hole transport layer 7, the light-emitting layer 38, and the electron transport layer 9 are layered between the anode 22 and the cathode 25 in this order from the anode 22 side will be described as an example, but the present embodiment is not limited thereto. For example, the light-emitting element 1 may be a light-emitting element having an inversely layered structure. In the case of the light-emitting element having the inversely layered structure, although not illustrated, the light-emitting element 1 includes the cathode 25 and the anode 22 provided as the upper layer than the cathode 25, and, for example, the electron transport layer 9, the light-emitting layer 38, and the hole transport layer 7 are layered between the cathode 25 and the anode 22 in this order from the cathode 25 side.

The light-emitting element 1 may be a top-emitting type or a bottom-emitting type. In order to make the light-emitting element having the normally layered structure the top-emitting type, the anode 22 can be formed of an electrode material that reflects visible light and the cathode 25 can be formed of an electrode material that transmits visible light. In order to make the light-emitting element having the normally layered structure the bottom-emitting type, the anode 22 can be formed of an electrode material that transmits visible light and the cathode 25 can be formed of an electrode material that reflects visible light. On the other hand, in order to make the light-emitting element having the inversely layered structure the top-emitting type, the cathode 25 can be formed of an electrode material that reflects visible light and the anode 22 provided as the upper layer than the cathode 25 can be formed of an electrode material that transmits visible light. In order to make the light-emitting element having the inversely layered structure the bottom-emitting type, the cathode 25 can be formed of an electrode material that transmits visible light and the anode 22 provided as the upper layer than the cathode 25 can be formed of an electrode material that reflects visible light.

The electrode material that reflects visible light is not particularly limited as long as the material can reflect visible light and has electrical conductivity, and examples thereof include metal materials such as Al, Mg, Li, and Ag, alloys of the metal materials, a layered body of the metal materials and transparent metal oxides (for example, indium tin oxide, indium zinc oxide, indium gallium zinc oxide, and the like), or a layered body of the alloys and the transparent metal oxides.

On the other hand, the electrode material that allows visible light to pass through is not particularly limited as long as the material can allow visible light to pass through and has electrical conductivity, and examples thereof include a thin film formed of a transparent metal oxide (for example, indium tin oxide, indium zinc oxide, indium gallium zinc oxide, and the like), a metal material such as Al and Ag, or a nano wire formed of a metal material such as Al and Ag.

The method for forming the light-emitting layer 38 provided in the light-emitting element 1 illustrated in FIG. 7 includes a step of forming at least part of the light-emitting layer 38 by using a first solution including the plurality of quantum dots 17, a precursor of the continuous compound 18b that forms the continuous compound 18b around each of the plurality of quantum dots 17, the electron transport material 10 having electron transport properties as the carrier transport material having carrier transport properties, and a solvent.

The entire light-emitting layer 38 may be formed by using the first solution. The light-emitting layer 38 may has the configuration in which the electron transport material 10 having electron transport properties is simply included or the configuration in which the electron transport material 10 having electron transport properties is uniformly dispersed. In the present embodiment, the first portion 8 of the light-emitting layer 38 is formed using a second solution described later, and then, the second portion 8′ of the light-emitting layer 38 is formed using the first solution, so that the concentration of the electron transport material 10 included in the second portion 8′ is higher than the concentration of the electron transport material 10 included in the first portion 8. In other words, the second solution is a solution prepared so that the concentration of the electron transport material 10 is lower than that of the first solution, and the difference between the second solution and the first solution lies only in the concentration. Also, in the present embodiment, the concentration of the electron transport material 10 included in the second solution may be 0.

In the above-described method for forming the light-emitting layer 38, when preparing each of the first solution and the second solution, the content of the precursor of the continuous compound may be decreased, and after forming part of the light-emitting layer 38 by using the first solution or the second solution, a solution including the precursor of the continuous compound may be additionally formed from above.

Each of the first solution and the second solution may include a ligand.

Examples of the solvent may include at least one of dimethyl sulfoxide (DMSO), N,N-dimethylformamide (DMF), N-methylformamide (NMF), formamide, N,N′-dimethylpropyleneurea, dimethylacetamide, N-methylpyrrolidone, gamma-butyrolactone, propylene carbonate, acetonitrile, 2-methoxyethanol, methyl acetate, ethyl acetate, ethyl formate, methyl formate, tetrahydrofuran, diethyl ether, tetrahydrothiophene, diethyl sulfide, octane, hexane, toluene, chlorobenzene, or chloroform.

The precursor of the compound 18b is, for example, the precursor of a metal sulfide, may include, for example, at least one of a metal acetate, a metal nitrate, or a metal halide as a metal source, and thiourea, N-methylthiourea, 1,3-dimethylthiourea, N,N′-dimethylthiourea, tetramethylthiourea, or thioacetamide as a sulfur source. Alternatively, the precursor of the metal sulfide may include a metal complex in which thiourea, N-methylthiourea, 1,3-dimethylthiourea, N,N′-dimethylthiourea, tetramethylthiourea, or thioacetamide is coordinated to a metal atom. Further, the precursor of the metal sulfide may be, for example, xanthic acid.

### Second Embodiment

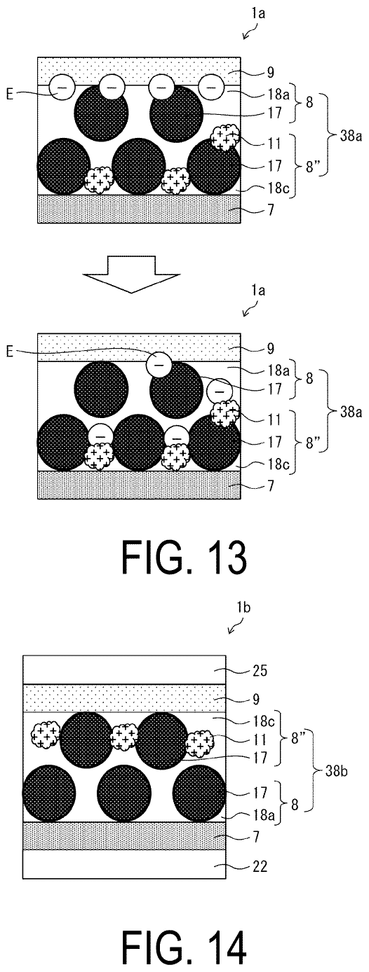

Next, a second embodiment of the disclosure will be described with reference to FIGS. 12 and 13. A light-emitting layer 38a provided in a light-emitting element 1a of the present embodiment is different from the light-emitting element 1 described in the first embodiment in that the light-emitting layer 38a includes a hole transport material 11 having hole transport properties as the carrier transport material having carrier transport properties. The other details are as described in the first embodiment. For convenience of description, members having the same functions as those shown in the drawings according to the first embodiment are denoted by the same reference numerals and signs, and descriptions thereof will be omitted.

FIG. 12 is a schematic cross-sectional view illustrating a schematic configuration of the light-emitting element 1a of the second embodiment.

As illustrated in FIG. 12, the light-emitting layer 38a provided in the light-emitting element 1a includes a first portion 8″ and a second portion 8. The first portion 8″ is provided closer to the anode 22 than the second portion 8, and the concentration of the hole transport material 11 having hole transport properties and included in the first portion 8″ is higher than the concentration of the hole transport material 11 having hole transport properties and included in the second portion 8.

In present embodiment, a case where the first portion 8″ is composed of the plurality of quantum dots 17, a continuous third compound 18c provided around each of the plurality of quantum dots 17, and the hole transport material 11 having hole transport properties, and the second portion 8 is composed of the plurality of quantum dots 17 and the continuous first compound 18a provided around each of the plurality of quantum dots 17 will be described as an example, but the present embodiment is not limited thereto. The hole transport material 11 having hole transport properties may be included also in the second portion 8 as long as the concentration of the hole transport material 11 having hole transport properties and included in the first portion 8″ is higher than the concentration of the hole transport material 11 having hole transport properties and included in the second portion 8. Furthermore, the light-emitting layer 38a may have a concentration gradient of the hole transport material 11 in which the concentration of the hole transport material 11 having hole transport properties gradually increases from the electron transport layer 9 toward the hole transport layer 7.

In the present embodiment, a case where each of the continuous third compound 18c and the continuous first compound 18a are the same inorganic compound will be described as an example, but the present embodiment is not limited thereto and the compounds may be different compounds.

The hole transport material 11 having hole transport properties may be nanoparticles of a metal oxide including at least one selected from Ni, Mg, Mo, Cu, Co, Cr, and Ti, and may be, for example, nanoparticles of a nickel oxide.

The hole transport material 11 having hole transport properties may be an organic monomer having hole transport properties, and the organic monomer having hole transport properties may be, for example, TAPC, TCTA, NPD, or TPD.

The hole transport material 11 having hole transport properties is preferably an organic semiconductor. In a case where the hole transport material 11 having hole transport properties is an inorganic semiconductor, there is a possibility that a change with a very small amount in the Fermi level due to contact between semiconductors causes a large change and a large barrier. On the other hand, in the case of the organic semiconductor, the change in the Fermi level due to contact between semiconductors is very gentle, and the dependence of the change in the Fermi level on contact amount is low. Thus, the hole level can be easily controlled, an injection barrier for the holes H is unlikely to be generated, and favorable injection characteristics for the holes H can be ensured.

The total weight of the hole transport material 11 having hole transport properties and included in the light-emitting layer 38a is preferably 10% or less, and more preferably 1% or less of the total weight of the plurality of quantum dots 17 included in the light-emitting layer 38a. The total weight of the hole transport material 11 having hole transport properties and included in the first portion 8″ is preferably about 70% or less of the total weight of the plurality of quantum dots 17 included in the first portion 8″. Within such a range, good injection characteristics of the hole H into the quantum dot 17 can be ensured.

FIG. 13 is views each for describing the reason why the electrons E are less likely to accumulate in the light-emitting layer 38a or at an interface between the light-emitting layer 38a and the electron transport layer 9 in the light-emitting element 1a of the second embodiment as compared with the light-emitting element 50 of comparative example 1 illustrated in FIG. 10.

The light-emitting element 50 of comparative example 1 illustrated in FIG. 10 and the light-emitting element 1a of the second embodiment illustrated in FIG. 13 are examples of the light-emitting elements in the electron-excess state.

In the case of the light-emitting element 1a of the second embodiment illustrated in FIG. 13, since the hole transport material 11 having hole transport properties is dispersed in the light-emitting layer 38a, the electrons E, which are excessively present carriers, are quenched and consumed by recombining with the hole transport material 11 having hole transport properties three-dimensionally present in the light-emitting layer 38a. In order to suppress the occurrence of light emission when the electrons E recombine with the hole transport material 11, it is preferable to use a non-light-emitting material as the hole transport material 11. As the non-light-emitting material, for example, a material having a band gap (Eg) of 3.5 eV or more can be used. According to the configuration of the light-emitting element 1a, the electrons E, which are excessively present carriers even when the time of the constant current driving period has elapsed, are less likely to accumulate, and the decrease in luminance of the light-emitting element 1a can be suppressed. Thus, according to the light-emitting element 1a, the carrier balance, the external quantum efficiency (EQE), and the reliability can be improved.

In addition, the electrons E, which are excessively present carriers even during the energization stop period, that is, the period during which the light-off state is maintained, are quenched and consumed by recombining with the hole transport material 11 having hole transport properties three-dimensionally present in the light-emitting layer 38a. Thus the luminance recovery in the energization stop period is fast in the light-emitting element 1a of the second embodiment.

In the light-emitting element 1a of the present embodiment, the case where the concentration of the hole transport material 11 having hole transport properties and included in the first portion 8″ is higher than the concentration of the hole transport material 11 having hole transport properties and included in the second portion 8 has been described as an example, but the present embodiment is not limited thereto. The hole transport material 11 having hole transport properties may be simply included in the light-emitting layer 38a or the hole transport material 11 having hole transport properties may be uniformly dispersed in the light-emitting layer 38a. In the case of the configuration in which the hole transport material 11 having hole transport properties is simply included in the light-emitting layer 38a or the configuration in which the hole transport material 11 having hole transport properties is uniformly dispersed in the light-emitting layer 38a, it is preferable that the hole transport material 11 having hole transport properties is not in contact with the electron transport layer 9.

### Third Embodiment

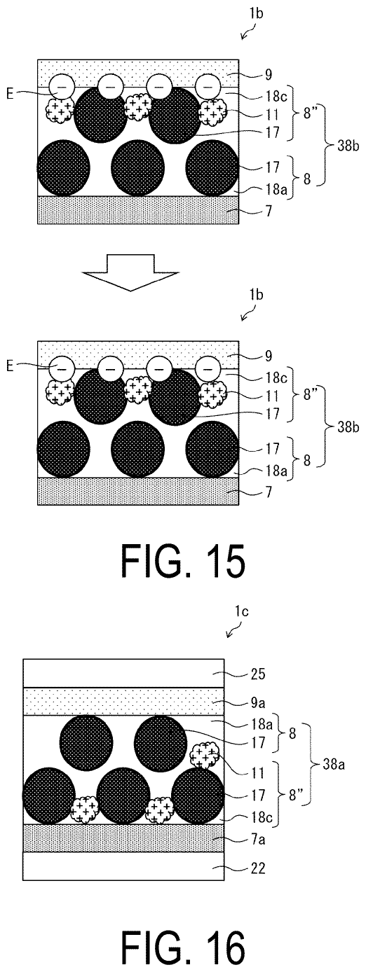

Next, a third embodiment of the disclosure will be described below with reference to FIG. 14 and FIG. 15. A light-emitting layer 38b provided in a light-emitting element 1b of the present embodiment is different from the light-emitting element 1a described in the second embodiment in that the concentration of the hole transport material 11 having hole transport properties and included in the second portion 8″ is higher than the concentration of the hole transport material 11 having hole transport properties and included in the first portion 8. The other details are as described in the first and second embodiments. For convenience of description, members having the same functions as those shown in the drawings according to the first and second embodiments are denoted by the same reference numerals and signs, and descriptions thereof will be omitted.

FIG. 14 is a schematic cross-sectional view illustrating a schematic configuration of the light-emitting element 1b of the third embodiment.

As illustrated in FIG. 14, the light-emitting layer 38b provided in the light-emitting element 1b includes a first portion 8 and a second portion 8″. The first portion 8 is provided closer to the anode 22 than the second portion 8″, and the concentration of the hole transport material 11 having hole transport properties and included in the second portion 8″ is higher than the concentration of the hole transport material 11 having hole transport properties and included in the first portion 8.

FIG. 15 is views each for describing the reason why the electrons E are less likely to accumulate in the light-emitting layer 38b or at an interface between the light-emitting layer 38b and the electron transport layer 9 in the light-emitting element 1b of the third embodiment as compared with the light-emitting element 50 of comparative example 1 illustrated in FIG. 10.

The light-emitting element 50 of comparative example 1 illustrated in FIG. 10 and the light-emitting element 1b of the third embodiment illustrated in FIG. 15 are examples of the light-emitting elements in the electron-excess state.

In the case of the light-emitting element 1b of the third embodiment illustrated in FIG. 15, since the hole transport material 11 having hole transport properties is dispersed in the light-emitting layer 38b, the electrons E, which are excessively present carriers, are quenched and consumed by recombining with the hole transport material 11 having hole transport properties three-dimensionally present in the light-emitting layer 38b. According to the configuration of the light-emitting element 1b, the electrons E, which are excessively present carriers even when the time of the constant current driving period has elapsed, are less likely to accumulate, and the decrease in luminance of the light-emitting element 1b can be suppressed. Thus, according to the light-emitting element 1b, the carrier balance, the external quantum efficiency (EQE), and the reliability can be improved.

In addition, the electrons E, which are excessively present carriers even during the energization stop period, that is, the period during which the light-off state is maintained, are quenched and consumed by recombining with the hole transport material 11 having hole transport properties three-dimensionally present in the light-emitting layer 38b. Thus the luminance recovery in the energization stop period is fast in the light-emitting element 1b of the third embodiment.

### Fourth Embodiment

Next, a fourth embodiment of the disclosure will be described with reference to FIGS. 16 to 18. A light-emitting element 1c of the present embodiment is different from the light-emitting element 1a described in the second embodiment in that the light-emitting element 1c is a light-emitting element in the hole-excess state. The others are as described in the second embodiment. For convenience of description, members having the same functions as those illustrated in the drawings of the second embodiment are denoted by the same reference numerals and signs, and descriptions thereof will be omitted.

FIG. 16 is a schematic cross-sectional view illustrating a schematic configuration of the light-emitting element 1c of the fourth embodiment.

As illustrated in FIG. 16, the light-emitting layer 38a provided in the light-emitting element 1c includes a first portion 8″ and a second portion 8. The first portion 8″ is provided closer to the anode 22 than the second portion 8, and the concentration of the hole transport material 11 having hole transport properties and included in the first portion 8″ is higher than the concentration of the hole transport material 11 having hole transport properties and included in the second portion 8.

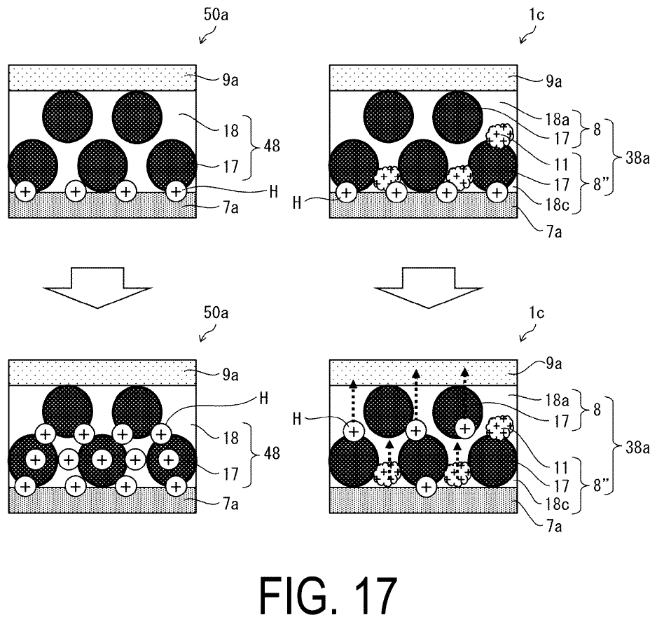

FIG. 17 is views each for describing the reason why the holes H are less likely to accumulate in the light-emitting layer 38a or at an interface between the light-emitting layer 38a and the hole transport layer 7a in the light-emitting element 1c of the fourth embodiment as compared with the light-emitting element 50a of comparative example 2.

The light-emitting element 50a of comparative example 2 and the light-emitting element 1c of the fourth embodiment illustrated in FIG. 17 are examples of the light-emitting elements in the hole-excess state.

In the case of the light-emitting element 50a of comparative example 2 illustrated in FIG. 17, the holes H, which are excessively present carriers, accumulate in the light-emitting layer 48 or at an interface between the light-emitting layer 48 and the hole transport layer 7a with a lapse of time of the constant current driving period, thus generating an electrical field in a direction opposite to the electrical field at the time of driving the light-emitting element 50a, and generating a decrease in luminance of the light-emitting element 50a. There is a problem in that such a decrease in luminance causes a decrease in luminous efficiency of the light-emitting element 50a. The electrical field in the opposite direction can be canceled by increasing the drive voltage of the light-emitting element 50a. However, in such a case, there is a problem in that a large stress is applied to the materials of the layers constituting the light-emitting element 50a and the reliability is greatly reduced.

On the other hand, in the case of the light-emitting element 1c of the fourth embodiment illustrated in FIG. 17, since the hole transport material 11 having hole transport properties is dispersed in the light-emitting layer 38a, the holes H, which are excessively present carriers, are gradually diffused to the electron transport layer 9a via the hole transport material 11 having hole transport properties three-dimensionally present around the holes H, and are quenched and consumed by recombining with the electron transport layer 9a. In order to suppress the occurrence of light emission when the holes H recombine with the electron transport layer 9a, it is preferable to use a non-light-emitting material as the electron transport layer 9a. As the non-light-emitting material, for example, a material having a band gap (Eg) of 3.5 eV or more can be used. According to the configuration of the light-emitting element 1c, the holes H, which are excessively present carriers even when the time of the constant current driving period has elapsed, are less likely to accumulate, and the decrease in luminance of the light-emitting element 1c can be suppressed. Thus, according to the light-emitting element 1c, the carrier balance, the external quantum efficiency (EQE), and the reliability can be improved.

The holes H, which are excessively present carriers even during the energization stop period, that is, the period during which the light-off state is maintained, are gradually diffused into the electron transport layer 9a via the hole transport material 11 having hole transport properties three-dimensionally present around the holes H, and are quenched and consumed by recombining with the electron transport layer 9a. Thus the luminance recovery in the energization stop period is fast in the light-emitting element 1c of the fourth embodiment.

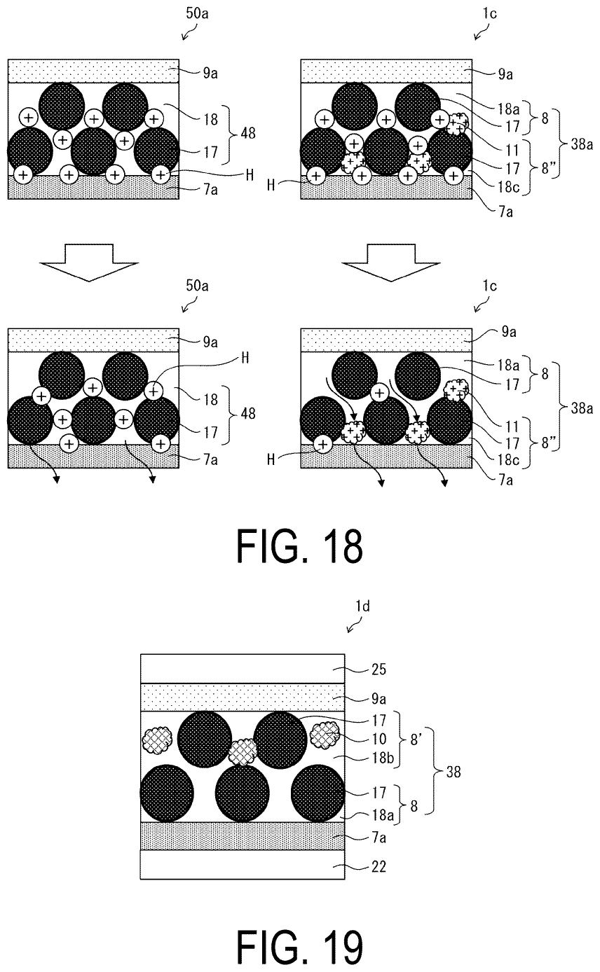

FIG. 18 is views each for describing the reason why the luminance recovery in the energization stop period is fast in the light-emitting element 1c of the fourth embodiment as compared with the light-emitting element 50a of comparative example 2.

In the light-emitting element 50a of comparative example 2 and the light-emitting element 1c of the fourth embodiment illustrated in FIG. 18, the holes H accumulated in the light-emitting layers 38a and 48 or at the interface between the light-emitting layers 38a and 48 and the hole transport layer 7a are gradually diffused toward the anode 22 side by maintaining the energization stop period, that is, the light-off state, and eventually return to a drive start initial state. However, in the case of the light-emitting element 50a of comparative example 2, as illustrated in FIG. 18, the holes H accumulated at the interface between the light-emitting layer 48 and the hole transport layer 7a are diffused to the anode 22 side at a relatively early stage of the energization stop period, but the holes H accumulated in the light-emitting layer 48 remain without being diffused to the anode 22 side even after a relatively long energization stop period has elapsed. Thus, in the light-emitting element 50a of comparative example 2, the luminance does not recover when an energization stop measure is performed for a short time, and the luminance can recover when the energization stop measure is performed for a long time, so that the luminance recovery in the energization stop period is slow.

On the other hand, in the case of the light-emitting element 1c of the fourth embodiment illustrated in FIG. 18, since the hole transport material 11 having hole transport properties is dispersed in the light-emitting layer 38a, the holes H accumulated in the light-emitting layer 38a or at the interface between the light-emitting layer 38a and the hole transport layer 7a are rapidly diffused to the anode 22 side via the hole transport material 11 having hole transport properties three-dimensionally present around the holes H. Thus, in the light-emitting element 1c of the fourth embodiment, the luminance recovery in the energization stop period is fast.

### Fifth Embodiment

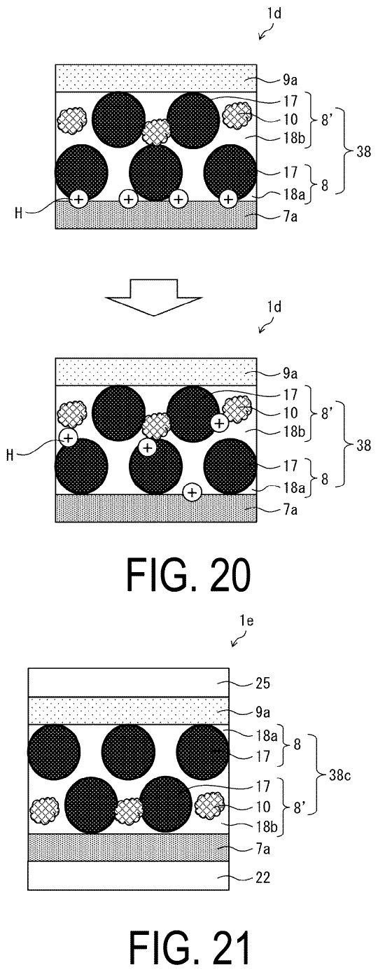

Next, a fifth embodiment of the disclosure will be described with reference to FIGS. 19 and 20. A light-emitting element 1d of the present embodiment is different from the light-emitting element 1 described in the first embodiment in that the light-emitting element 1d is a light-emitting element in the hole-excess state. The other details are as described in the first embodiment. For convenience of description, members having the same functions as those shown in the drawings according to the first embodiment are denoted by the same reference numerals and signs, and descriptions thereof will be omitted.

FIG. 19 is a schematic cross-sectional view illustrating a schematic configuration of the light-emitting element 1d of the fifth embodiment.

As illustrated in FIG. 19, the light-emitting layer 38 provided in the light-emitting element 1d includes a first portion 8 and a second portion 8′. The first portion 8 is provided closer to the anode 22 than the second portion 8′, and a concentration of the electron transport material 10 having electron transport properties and included in the second portion 8′ is higher than a concentration of the electron transport material 10 having electron transport properties and included in the first portion 8.

FIG. 20 is views each for describing the reason why the holes H are less likely to accumulate in the light-emitting layer 38 or at an interface between the light-emitting layer 38 and the hole transport layer 7a in the light-emitting element 1d of the fifth embodiment as compared with the light-emitting element 50a of comparative example 2 illustrated in FIG. 17.

In the case of the light-emitting element 1d of the fifth embodiment illustrated in FIG. 20, since the electron transport material 10 having electron transport properties is dispersed in the light-emitting layer 38, the holes H, which are excessively present carriers, are quenched and consumed by recombining with the electron transport material 10 having electron transport properties three-dimensionally present. In order to suppress the occurrence of light emission when the holes H recombine with the electron transport material 10, it is preferable to use a non-light-emitting material as the electron transport material 10. As the non-light-emitting material, for example, a material having a band gap (Eg) of 3.5 eV or more can be used. According to the configuration of the light-emitting element 1d, the holes H, which are excessively present carriers even when the time of the constant current driving period has elapsed, are less likely to accumulate, and the decrease in luminance of the light-emitting element 1d can be suppressed. Thus, according to the light-emitting element 1d, the carrier balance, the external quantum efficiency (EQE), and the reliability can be improved.

In addition, the holes H, which are excessively present carriers even during the energization stop period, that is, the period during which the light-off state is maintained, are quenched and consumed by recombining with the electron transport material 10 having electron transport properties three-dimensionally present. Thus the luminance recovery in the energization stop period is fast in the light-emitting element 1d of the fifth embodiment.

### Sixth Embodiment

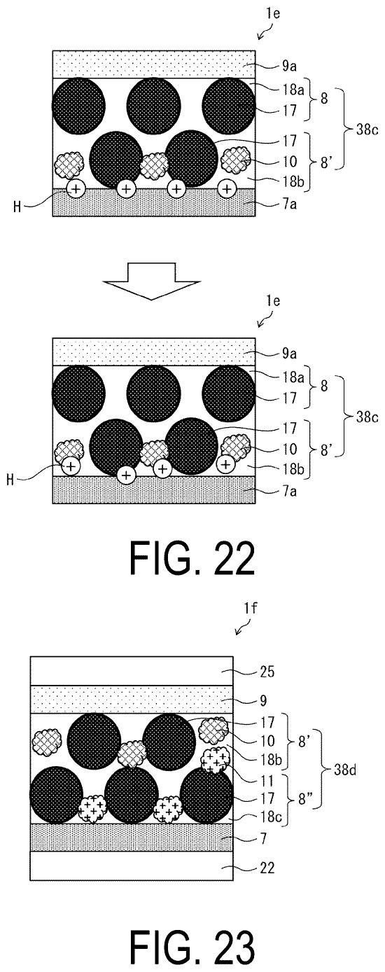

Next, a sixth embodiment according to the disclosure will be described with reference to FIG. 21 and FIG. 22. A light-emitting element 1e of the present embodiment is a light-emitting element in the hole-excess state, and is different from the light-emitting elements described in the first to fifth embodiments in that the concentration of the electron transport material 10 having electron transport properties and included in the first portion 8′ of a light-emitting layer 38c is higher than the concentration of the electron transport material 10 having electron transport properties and included in the second portion 8. The others are as described in the first to fifth embodiments. For convenience of explanation, components having the same functions as those illustrated in diagrams of the first to fifth embodiments are appended with the same reference signs, and descriptions thereof may be omitted.

FIG. 21 is a schematic cross-sectional view illustrating a schematic configuration of the light-emitting element 1e of the sixth embodiment.

As illustrated in FIG. 21, the first portion 8′ of the light-emitting layer 38c is provided closer to the anode 22 than the second portion 8 of the light-emitting layer 38c. The concentration of the electron transport material 10 having electron transport properties and included in the first portion 8′ is higher than the concentration of the electron transport material 10 having electron transport properties and included in the second portion 8.

FIG. 22 is views each for describing the reason why the holes H are less likely to accumulate in the light-emitting layer 38c or at an interface between the light-emitting layer 38c and the hole transport layer 7a in the light-emitting element 1e of the sixth embodiment as compared with the light-emitting element 50a of comparative example 2 illustrated in FIG. 17.

In the case of the light-emitting element 1e of the sixth embodiment illustrated in FIG. 22, since the electron transport material 10 having electron transport properties is dispersed in the light-emitting layer 38c, the holes H, which are excessively present carriers, are quenched and consumed by recombining with the electron transport material 10 having electron transport properties three-dimensionally present. According to the configuration of the light-emitting element 1e, the holes H, which are excessively present carriers even when the time of the constant current driving period has elapsed, are less likely to accumulate, and the decrease in luminance of the light-emitting element 1e can be suppressed. Thus, according to the light-emitting element 1e, the carrier balance, the external quantum efficiency (EQE), and the reliability can be improved.

In addition, the holes H, which are excessively present carriers even during the energization stop period, that is, the period during which the light-off state is maintained, are quenched and consumed by recombining with the electron transport material 10 having electron transport properties three-dimensionally present. Thus the luminance recovery in the energization stop period is fast in the light-emitting element 1e of the sixth embodiment.

### Seventh Embodiment

Next, a seventh embodiment of the disclosure will be described with reference to FIG. 23. A light-emitting element 1f of the present embodiment is a light-emitting element in the electron-excess state, and is different from the light-emitting elements described in the first to sixth embodiments in that a light-emitting layer 38d includes both the electron transport material 10 having electron transport properties and the hole transport material 11 having hole transport properties. The others are as described in the first to sixth embodiments. For convenience of explanation, components having the same functions as those illustrated in diagrams of the first to sixth embodiments are appended with the same reference signs, and descriptions thereof may be omitted.

FIG. 23 is a schematic cross-sectional view illustrating a schematic configuration of the light-emitting element 1f of the seventh embodiment.

As illustrated in FIG. 23, the light-emitting layer 38d includes a first portion 8″ and a second portion 8′, and the first portion 8″ is provided closer to the anode 22 than the second portion 8′. The concentration of the hole transport material 11 having hole transport properties and included in the first portion 8″ is higher than the concentration of the hole transport material 11 having hole transport properties and included in the second portion 8′, and the concentration of the electron transport material 10 having electron transport properties and included in the second portion 8′ is higher than the concentration of the electron transport material 10 having electron transport properties and included in the first portion 8″.

According to the light-emitting element 1f of the seventh embodiment, it is possible to obtain both the effect of making the electrons E, which are excessively present carriers, be further less likely to accumulate and the effect of rapidly diffusing the electrons E, which are excessively present carriers, toward the cathode 25 side.

### Eighth Embodiment

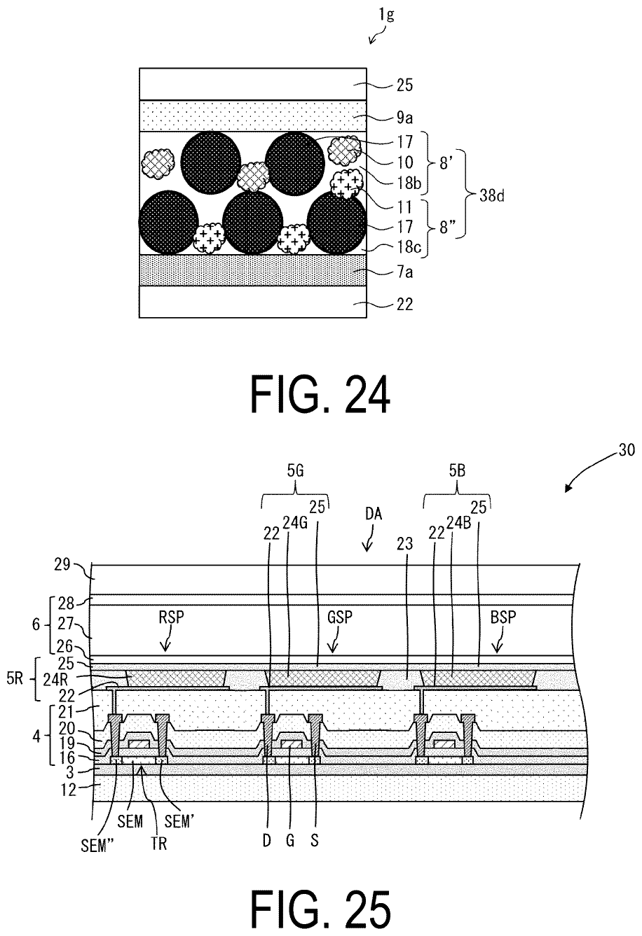

Next, an eighth embodiment of the disclosure will be described with reference to FIG. 24. A light-emitting element 1g of the present embodiment is different from the light-emitting element 1f described in the seventh embodiment in that the light-emitting element 1g is a light-emitting element in the hole-excess state. Other configurations are as described in the seventh embodiment. For convenience of explanation, components having the same functions as those described in diagrams of the seventh embodiment are denoted by the same reference numerals, and descriptions thereof will be omitted.

FIG. 24 is a schematic cross-sectional view illustrating a schematic configuration of the light-emitting element 1g of the eighth embodiment.

As illustrated in FIG. 24, the light-emitting layer 38d includes a first portion 8″ and a second portion 8′, and the first portion 8″ is provided closer to the anode 22 than the second portion 8′. The concentration of the hole transport material 11 having hole transport properties and included in the first portion 8″ is higher than the concentration of the hole transport material 11 having hole transport properties and included in the second portion 8′, and the concentration of the electron transport material 10 having electron transport properties and included in the second portion 8′ is higher than the concentration of the electron transport material 10 having electron transport properties and included in the first portion 8″.

According to the light-emitting element 1g of the seventh embodiment, it is possible to obtain both the effect of making the holes H, which are excessively present carriers, be further less likely to accumulate and the effect of rapidly diffusing the holes H, which are excessively present carriers, toward the anode 22 side.

### Ninth Embodiment

Next, a ninth embodiment of the disclosure will be described with reference to FIG. 25.

A display device 30 of the present embodiment is different from the first to eighth embodiments in that the display device 30 includes the light-emitting elements 1 to 1g. The others are as described in the first to eighth embodiments. For convenience of description, members having the same functions as those illustrated in the drawings according to the first to eighth embodiments are denoted by the same reference numerals and signs, and descriptions thereof will be omitted.

FIG. 25 is a schematic cross-sectional view illustrating a schematic configuration of the display device 30 of the ninth embodiment.

As illustrated in FIG. 25, the display device 30 includes a first light-emitting element 5R that emits light of a first color (for example, red), a second light-emitting element 5G that emits light of a second color (for example, green) whose light-emission peak wavelength is shorter than that of the light of the first color, and a third light-emitting element 5B that emits light of a third color (for example, blue) whose light-emission peak wavelength is shorter than that of the light of the second color. The third light-emitting element 5B is any of the light-emitting elements 1 to 1g of the first to eighth embodiments described above.

In the present embodiment, the case where the third light-emitting element 5B is any of the light-emitting elements 1 to 1g in the first to eighth embodiments described above has been described as an example, but the present embodiment is not limited thereto. At least one of the first light-emitting element 5R, the second light-emitting element 5G, or the third light-emitting element 5B may be any of the light-emitting elements 1 to 1g in the first to eighth embodiments described above.

As illustrated in FIG. 25, a red subpixel RSP of the display device 30 includes the first light-emitting element 5R including a function layer 24R including a red light-emitting layer, a green subpixel GSP of the display device 30 includes the second light-emitting element 5G including a function layer 24G including a green light-emitting layer, and a blue subpixel BSP of the display device 30 includes the third light-emitting element 5B including a function layer 24B including a blue light-emitting layer.

As illustrated in FIG. 25, in a display region DA of the display device 30, a barrier layer 3, a thin film transistor layer 4 including transistors TR, the first light-emitting element 5R, the second light-emitting element 5G, the third light-emitting element 5B, banks 23, a sealing layer 6, and a function film 29 are provided on a substrate 12 in this order from the substrate 12 side.

The substrate 12 may be, for example, a resin substrate made of a resin material such as a polyimide, or may be a glass substrate. In the present embodiment, the display device 30 is a flexible display device, and thus a case will be described as an example in which a resin substrate made of the resin material such as a polyimide is used as the substrate 12; however, the disclosure is not limited thereto. In a case that the display device 30 is a non-flexible display device, the glass substrate may be used as the substrate 12.

The barrier layer 3 is a layer that inhibits foreign matter, such as water and oxygen, from entering the transistor TR, the first light-emitting element 5R, the second light-emitting element 5G, and the third light-emitting element 5B, and can be formed of, for example, a silicon oxide film, a silicon nitride film, or a silicon oxynitride film, or a layered film thereof formed by using a chemical vapor deposition (CVD) method.

The transistor TR portion of the thin film transistor layer 4 including the transistor TR includes a semiconductor film SEM, doped semiconductor films SEM′ and SEM″, an inorganic insulating film 16, a gate electrode G, an inorganic insulating film 19, an inorganic insulating film 20, a source electrode S, a drain electrode D, and a flattening film 21, and a portion other than the transistor TR portion of the thin film transistor layer 4 including the transistor TR includes the inorganic insulating film 16, the inorganic insulating film 19, the inorganic insulating film 20, and the flattening film 21.

The semiconductor films SEM, SEM′ and SEM″ may be formed of low-temperature polysilicon (LTPS) or an oxide semiconductor (for example, an In—Ga—Zn—O based semiconductor), for example. Although a case in which the transistor TR has a top gate structure is exemplified in the present embodiment, the disclosure is not limited thereto, and the transistor TR may have a bottom gate structure.

The gate electrode G, the source electrode S, and the drain electrode D may be formed of a single-layer film or a layered film of a metal including, for example, at least one of aluminum, tungsten, molybdenum, tantalum, chromium, titanium, or copper.

The inorganic insulating film 16, the inorganic insulating film 19, and the inorganic insulating film 20 can be formed of, for example, a silicon oxide film, a silicon nitride film, or a silicon oxynitride film, or a layered film thereof, formed by using the CVD method.

The flattening film 21 can be formed of coatable organic materials such as a polyimide and acrylic material, but may be formed of an inorganic film.

The first light-emitting element 5R included in the red subpixel RSP includes the anode 22 that is an upper layer overlying the flattening film 21, the function layer 24R including the red light-emitting layer, and the cathode 25. The second light-emitting element 5G included in the green subpixel GSP includes the anode 22 that is an upper layer overlying the flattening film 21, the function layer 24G including the green light-emitting layer, and the cathode 25. The third light-emitting element 5B included in the blue subpixel BSP includes the anode 22 that is an upper layer overlying the flattening film 21, the function layer 24B including the blue light-emitting layer, and the cathode 25. Note that the bank 23 with insulating properties covering the edge of the anode 22 is formed, for example, by applying an organic material, such as polyimide or acrylic, and then patterning the organic material by photolithography but may be formed of an inorganic film.

According to the display device 30 described above, the carrier balance, the external quantum efficiency (EQE), and the reliability can be improved.

### APPENDIX

The disclosure is not limited to the embodiments described above, and various modifications may be made within the scope of the claims. Embodiments obtained by appropriately combining technical approaches disclosed in the different embodiments also fall within the technical scope of the disclosure. Furthermore, novel technical features can be formed by combining the technical approaches disclosed in each of the embodiments.

### INDUSTRIAL APPLICABILITY

The disclosure may be utilized in a light-emitting element, a display device, and a method for forming a light-emitting layer.

1. A light-emitting element comprising:
an anode;
a cathode; and
a light-emitting layer provided between the anode and the cathode,
wherein the light-emitting layer includes
a plurality of quantum dots,
a continuous compound provided around each of the plurality of quantum dots, and
a carrier transport material having carrier transport properties,
wherein the continuous compound is a matrix of an inorganic compound, and
the matrix of the inorganic compound includes the carrier transport material.

2. (canceled)

3. (canceled)

4. The light-emitting element according to claim 1,
wherein the carrier transport material having carrier transport properties is a hole transport material having hole transport properties,
the light-emitting layer includes a first portion and a second portion,
the first portion is provided closer to the anode than the second portion, and
a concentration of the hole transport material having hole transport properties and included in the first portion is higher than a concentration of the hole transport material having hole transport properties and included in the second portion.

5. The light-emitting element according to claim 1,
wherein the carrier transport material having carrier transport properties is an electron transport material having electron transport properties,
the light-emitting layer includes a first portion and a second portion,
the first portion is provided closer to the anode than the second portion, and
a concentration of the electron transport material having electron transport properties and included in the second portion is higher than a concentration of the electron transport material having electron transport properties and included in the first portion.

6. The light-emitting element according to claim 1,
wherein the carrier transport material having carrier transport properties is a hole transport material having hole transport properties,
the light-emitting layer includes a first portion and a second portion,
the first portion is provided closer to the anode than the second portion, and
a concentration of the hole transport material having hole transport properties and included in the second portion is higher than a concentration of the hole transport material having hole transport properties and included in the first portion.

7. The light-emitting element according to claim 1,
wherein the carrier transport material having carrier transport properties is an electron transport material having electron transport properties,
the light-emitting layer includes a first portion and a second portion,
the first portion is provided closer to the anode than the second portion, and
a concentration of the electron transport material having electron transport properties and included in the first portion is higher than a concentration of the electron transport material having electron transport properties and included in the second portion.

8. The light-emitting element according to claim 1,
wherein the carrier transport material having carrier transport properties is composed of a plurality of types of carrier transport materials,
part of the plurality of types of carrier transport materials each having the carrier transport properties is a hole transport material having hole transport properties,
a remaining part of the plurality of types of the carrier transport materials each having the carrier transport properties is an electron transport material having electron transport properties,
the light-emitting layer includes a first portion and a second portion,
the first portion is provided closer to the anode than the second portion,
a concentration of the hole transport material having hole transport properties and included in the first portion is higher than a concentration of the hole transport material having hole transport properties and included in the second portion, and
a concentration of the electron transport material having electron transport properties and included in the second portion is higher than a concentration of the electron transport material having electron transport properties and included in the first portion.

9. The light emitting element according to claim 4,
wherein the hole transport material having hole transport properties is nanoparticles of a metal oxide including at least one selected from Ni, Mg, Mo, Cu, Co, Cr, and Ti.

10. The light-emitting element according to claim 9,
wherein the nanoparticles of a metal oxide is nanoparticles of a nickel oxide.

11. The light-emitting element according to claim 4,
wherein the hole transport material having hole transport properties is an organic monomer having hole transport properties.

12. The light-emitting element according to claim 5,
wherein the electron transport material having electron transport properties is nanoparticles of a metal oxide including at least one selected from Zn, Mg, Ti, Si, Sn, W, Ta, Ba, Zr, Al, Y, and Hf.

13. The light-emitting element according to claim 12,
wherein the nanoparticles of a metal oxide is nanoparticles of a zinc oxide or a magnesium zinc oxide.

14. The light-emitting element according to claim 5,
wherein the electron transport material having electron transport properties is an organic monomer having electron transport properties.

15. The light-emitting element according to claim 1,
wherein a hole function layer is provided between the anode and the light-emitting layer,
an electron function layer is provided between the cathode and the light-emitting layer.

16. The light-emitting element according to claim 15,
wherein the hole function layer includes a hole transport layer and a hole injection layer, and
the electron function layer includes an electron transport layer and an electron injection layer.

17. A display device comprising:
a first light-emitting element configured to emit light of a first color;
a second light-emitting element configured to emit light of a second color having a light-emission peak wavelength shorter than a light-emission peak wavelength of the light of the first color; and
a third light-emitting element configured to emit light of a third color having a light-emission peak wavelength shorter than a light-emission peak wavelength of the light of the second color,
wherein the third light-emitting element is the light-emitting element according to claim 1.

18. (canceled)

19. (canceled)

20. (canceled)

21. A light-emitting element comprising:
an anode;
a cathode; and
a light-emitting layer provided between the anode and the cathode,
wherein the light-emitting layer includes
a plurality of quantum dots,
a continuous compound provided around each of the plurality of quantum dots, and
a carrier transport material having carrier transport properties,
wherein the carrier transport material having carrier transport properties is a hole transport material having hole transport properties,
the light-emitting layer includes a first portion and a second portion,
the first portion is provided closer to the anode than the second portion, and
a concentration of the hole transport material having hole transport properties and included in the first portion is higher than a concentration of the hole transport material having hole transport properties and included in the second portion.

22. A light-emitting element comprising:
an anode;
a cathode; and
a light-emitting layer provided between the anode and the cathode,
wherein the light-emitting layer includes
a plurality of quantum dots,
a continuous compound provided around each of the plurality of quantum dots, and
a carrier transport material having carrier transport properties,
wherein the carrier transport material having carrier transport properties is an electron transport material having electron transport properties,
the light-emitting layer includes a first portion and a second portion,
the first portion is provided closer to the anode than the second portion, and a concentration of the electron transport material having electron transport properties and included in the second portion is higher than a concentration of the electron transport material having electron transport properties and included in the first portion.

23. The light-emitting element according to claim 21,
wherein the continuous compound is a matrix including at least one selected from
an inorganic compound, an organic polymer compound, and an organic and inorganic hybrid compound.

24. The light-emitting element according to claim 22,
wherein the continuous compound is a matrix including at least one selected from
an inorganic compound, an organic polymer compound, and an organic and inorganic hybrid compound.
